(19) United States
(12) Patent Application Publication
(10) Pub. No.: US 2006/0128154 A1
(43) Pub. Date: Jun. 15, 2006

(54) Glass substrate for magnetic disk and its production process

(75) Inventors: Osamu Miyahara, Yokohama-shi (JP); Masami Kaneko, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Asahi Glass Company, Limited, Chiyoda-ku (JP)

(21) Appl. No.: 11/293,292

(22) Filed: Dec. 5, 2005

(30) Foreign Application Priority Data
Dec. 15, 2004 (JP) 2004-363495

(51) Int. Cl. H01L 21/461

(52) U.S. Cl. 438/692; 360/98.08; 438/689

(57) ABSTRACT

A doughnut-type glass substrate for a magnetic disk having a circular hole at its center, characterized in that its inner peripheral edge surface is an etched surface with a large number of pits having different curvature radii adjacent to one another, and the proportion of pits having curvature radii r of at most 0.5 μm is at most 5% to all the pits on the etched surface.

The present invention relates to a glass substrate for a magnetic disk having an inner peripheral edge surface having an etching treatment applied thereto.

As a doughnut-type substrate to be used for e.g. magnetic disk memory devices, an aluminum alloy substrate has been mainly employed. However, along with the demand for high density recording, a glass substrate has now been employed which is excellent in flatness and smoothness and of which the base material itself is hard as compared with an aluminum alloy substrate. However, a doughnut-type glass substrate (hereinafter sometimes referred to simply as a glass substrate) made of glass which is a brittle material, is likely to break during handling or during use, which is regarded as one of the problems.

One of factors governing the mechanical strength of a doughnut-type glass substrate is scars which are present on the inner peripheral edge surface of the glass substrate where the maximum tensile stress will be exerted by high speed rotation during use of the magnetic disks. In order to reduce the depth of scars on the inner peripheral edge surface and the outer peripheral edge surface (hereinafter sometimes they will generally be referred to as the inner and outer peripheral edge surfaces) of the glass substrate and thereby to improve the mechanical strength, finish processing of the inner and outer peripheral edge surfaces is carried out with abrasive grains finer than #500 mesh, but considerably deep scars may still remain on the inner and outer peripheral edge surfaces. The inner and outer peripheral edge surfaces tend to have deteriorated smoothness due to such scars, whereby particles are likely to be generated, i.e. dust is likely to be generated. Particularly, dust is likely to be generated from the inner peripheral edge surface which holds the magnetic disk.

Most of the particles generated from the inner and outer peripheral edges surfaces of the glass substrate are fine glass particles or impurities attached to the edge surfaces, having an average particle size at a level of from 0.1 to 3.0 μm for example, generated by separation of part of the glass at the edge surfaces, and lead to defective magnetic disks or a decrease in quality, in production of the magnetic disks or during their use. Particularly, for magnetic disk memory devices for high density recording in recent years, the dust generated from the inner and outer peripheral edge surfaces of the glass substrate together with mechanical strength is a major concern, and a countermeasure thereaginst has been strongly desired.

JP-A-7-230621 discloses to apply an etching treatment to a glass substrate by means of an etching liquid such as hydrofluoric acid or hydrofluoric sulfuric acid to reduce the surface roughness of particularly an inner peripheral edge surface, which governs the strength of the glass substrate. By applying an etching treatment to an edge surface of a glass substrate by such a method, it is possible to reduce or remove scars present on the edge surface by etching to reduce the surface roughness, thereby to improve mechanical strength of the glass substrate.

However, although the etching method as disclosed in JP-A-7-230621 is effective to improve strength of the glass substrate, its effect of preventing dust generation is insufficient, and the yield tends to decrease due to generation of dust exceeding tolerance in many cases. Namely, although mechanical strength of the glass substrate can be improved, the problem of the dust generation has remained unsolved and the productivity has been greatly impaired.

Further, JP-A-11-328665 discloses, to further improve the strength of a glass substrate having an etching treatment applied thereto, to cover the etched inner peripheral edge surface with a protective film obtained by curing a coating composition containing a polysilazane for example. The protective film which covers the inner peripheral edge surface is useful to reduce the scars remaining on the edge surface to improve the strength and at the same time, to prevent generation of dust. However, in such a method, since two steps of an etching treatment to the inner peripheral edge surface and covering with a protective film are required, the production cost is very high due to a burden of the covering with a protective film and complicated process for production of the glass substrate, such being practically problematic.

Under these circumstances, it is an object of the present invention to solve the above problems of a glass substrate for a magnetic disk and to provide a doughnut-type glass substrate for a magnetic disk, having mechanical strength of its inner peripheral edge surface improved and generation of dust prevented, only by applying an etching treatment to the inner peripheral edge surface.

To achieve the above object, the present inventors have conducted extensive studied on an etched inner peripheral edge surface of a glass substrate for a magnetic disk and as a result, found the following. Namely, a large number of dents (hereinafter referred to as pits) having different curvature radii are adjacent to one another on the etched surface, a large amount of dust tends to be generated if the proportion of pits having small curvature radii is large, and improvement in mechanical strength and prevention of dust generation can be simultaneously achieved by improving the properties of the etched surface. They have further found that covering with a protective film is not necessarily required, and that a high quality glass substrate for a magnetic disk can be obtained at a low cost only by an etching treatment.

Namely, the present invention provides a doughnut-type glass substrate for a magnetic disk having a circular hole at its center, characterized in that its inner peripheral edge surface is an etched surface with a large number of pits having different curvature radii adjacent to one another, and the proportion of pits having curvature radii r of at most 0.5 μm is at most 5% to all the pits on the etched surface.

In the above glass substrate for a magnetic disk, the proportion of pits having curvature radii r of at most 1.0 μm is preferably at most 20% to all the pits on the etched surface. Further, the proportion of pits having curvature radii r of at most 3.0 μm is preferably at most 85% to all the pits on the etched surface. Further, the outer peripheral edge surface may be an etched surface similar to the inner peripheral edge surface.

The present invention further provides a process for producing the above glass substrate for a magnetic disk, which comprises subjecting the inner peripheral edge surface of the doughnut-type glass substrate having a circular hole at its center to finish polishing so that the surface roughness Ra is at most 1.0 μm, and then applying an etching treatment to the finish polished surface in an etching amount of at least 2.5 μm.

Still further, the present invention provides a process for producing a glass substrate for a magnetic disk, which comprises subjecting an inner peripheral edge surface of a doughnut-type glass substrate having a circular hole at its center, made of a glass having a total content of alkali metal oxides of from 6 to 12 mass %, to finish polishing so that the surface roughness Ra is at most 1.0 μm, and then applying an etching treatment to the finish polished surface in an etching amount of from 2.5 to 25 μm.

According to the present invention, at least an inner peripheral edge surface of a doughnut-type glass substrate having a circular hole at its center is an etched surface with a large number of pits having different curvature radii adjacent to one another, and the proportion of pits having curvature radii r of at most 0.5 μm is at most 5% to all the pits on the etched surface, whereby further improvement in mechanical strength of the glass substrate and further prevention of dust generation from the edge surface can be achieved. Further, when the proportion of pits having curvature radii r of at most 1.0 μm is at most 20% to all the pits on the etched surface, or when the proportion of pits having curvature radii r of at most 3.0 μm is at most 85% to all the pits on the etched surface, dust generation from the edge surface can be furthermore prevented. Still further, when the outer peripheral edge surface is an etched surface similar to the inner peripheral edge surface, an effect of preventing dust generation from the outer peripheral edge surface can also be achieved.

Further, according to the present invention, it is possible to produce a high quality glass substrate for a magnetic disk, from which dust generation is suppressed, at a low cost, by subjecting an inner peripheral edge surface of a doughnut-type glass substrate having a circular hole at its center to finish polishing so that the surface roughness Ra is at most 1.0 μm and then applying an etching treatment to the finish polished surface in a polishing amount of at least 2.5 μm.

In the accompanying drawings:

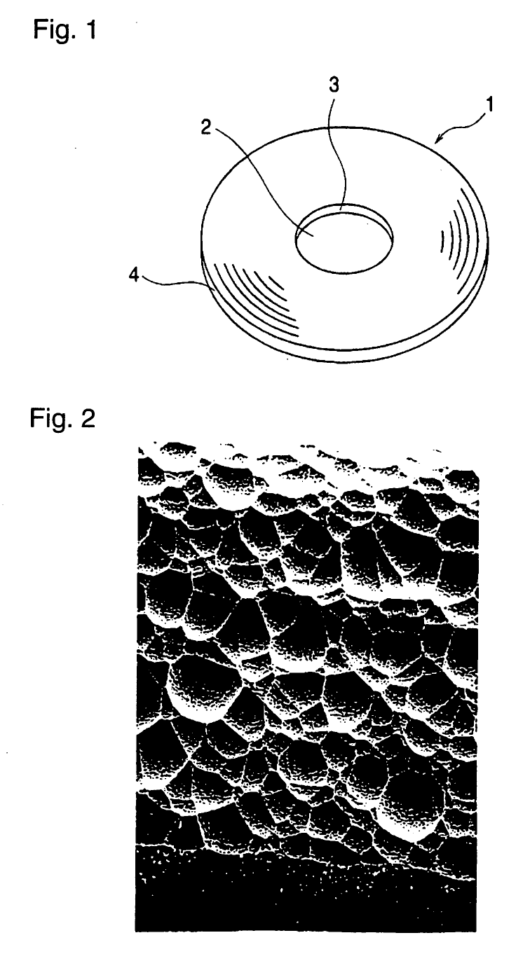

FIG. 1 is a perspective view illustrating a doughnut-type glass substrate of the present invention.

FIG. 2 is a scanning electron micrograph of an etched surface of the glass substrate shown in FIG. 1.

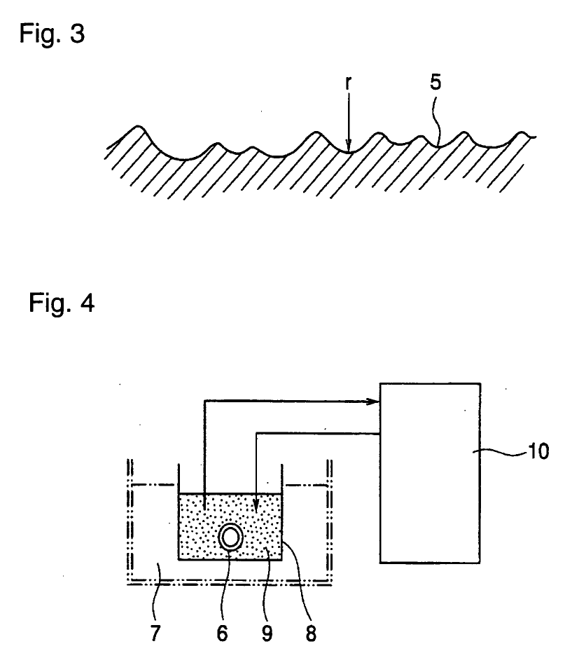

FIG. 3 is an enlarged sectional view schematically illustrating the etched surface shown in FIG. 2.

FIG. 4 is a drawing schematically illustrating a dust amount measurement apparatus.

Now, the present invention will be described in detail with reference to the preferred embodiments.

The doughnut-type glass substrate of the present invention is a doughnut-type glass substrate having a circular disk shape with a predetermined radius and having a circular cut hole having substantially the same center as the center of the disk at a center portion of the disk, and having an inner peripheral edge surface, an outer peripheral edge surface and front and back main surfaces. In the following description, the glass substrate means such a doughnut-type glass substrate.

The dimensions of the doughnut-type glass substrate are not particularly limited, and the dimensions as represented by mm may, for example, be such that (a) inner diameter 7.0, outer diameter 27.1, plate thickness 0.38, (b) inner diameter 12.0, outer diameter 48.0, plate thickness 0.55, (c) inner diameter 25.0, outer diameter 84.0, plate thickness 1.0, (d) inner diameter 12.0, outer diameter 48.0, plate thickness 0.5, or (e) inner diameter 25.0, outer diameter 95.0, plate thickness 0.8.

The type of glass to be used for the doughnut-type glass substrate of the present invention is preferably a glass having the following characteristics, for the improvement of the weather resistance. However, the glass is not limited thereto.

Water resistance: When the glass is immersed in water of 80° C. for 24 hours, the weight reduction of the glass (eluted amount) due to elution of components from the glass, is not more than 0.02 mg/cm².

Acid resistance: When the glass is immersed in a 0.1 N hydrochloric acid aqueous solution of 80° C. for 24 hours, the weight reduction of the glass (eluted amount) due to elution of components from the glass, is not more than 0.06 mg/cm².

Alkali resistance: When the glass is immersed in a 0.1 N sodium hydroxide aqueous solution of 80° C. for 24 hours, the weight reduction of the glass (eluted amount) due to elution of components from the glass is not more than 1 mg/cm², more preferably not more than 0.18 mg/cm².

The glass to be used for the glass substrate of the present invention may, for example, be a glass having a total content of alkali metal oxides of from 1 to 20 mass % (such as soda lime silica glass having an alkali metal oxide content of about 13 mass %), alumina silicate glass, alkali-free glass or crystallized glass, which satisfies characteristics and physical properties of a magnetic disk substrate. In a case where it is glass containing an alkali metal oxide, the total content of alkali metal oxides is typically from 6 to 12 mass %.

The brittleness index (B) of the glass to be used for the glass substrate of the present invention is preferably at least 5,500 m^{-1/2}, more preferably at least 7,000 m^{-1/2}.

The brittleness index is to quantitatively evaluate brittleness from the relation between the size of a trace of a Vickers indenter left on a glass surface after the indenter is pressed against the glass, and the length of cracks generated at four corners of the trace. Namely, B calculated from the following formula is the brittleness index, where P is a pressing load of the Vickers indenter, “a” is the width across corner of the Vickers trace and c is the length of cracks generated at four corners of the Vickers trace (the total length of symmetric two cracks including the trace of the indenter) (JP-A-10-152338):
c/a=0.0056×B^{2/3}×P^{1/6}

The present invention is characterized in that at least inner peripheral edge surface of a doughnut-type glass substrate is an etched surface with a large number of pits having different curvature radii adjacent to one another, and the proportion of pits having curvature radii r of at most 0.5 μm is at most 5% to all the pits on the etched surface. Now, this characteristics will be explained in detail with reference to Figs.

FIG. 1 is a perspective view illustrating a doughnut-type glass substrate 1 of the present invention, and the glass substrate is, as mentioned above, a disk shape glass substrate having a concentric circular hole 2 having substantially the same center as the center of the disk at a center portion of the disk, and has an inner peripheral edge surface 3 and an outer peripheral edge surface 4 at its inner periphery and outer periphery. The thickness of the glass substrate is not limited but is usually from about 0.38 to about 1.1 mm. The inner peripheral edge surface 3 and the outer peripheral edge surface 4 are subjected to finish polishing with diamond abrasive grains smaller than #500 mesh, and then an etching treatment is applied to at least the inner peripheral edge surface. When an etching treatment is applied to the finish polished surface, fine concaves and convexes are etched thereby to form concaves. Such concaves gradually become spherical and become pits which are spherical or close to spherical by continued etching, and adjacent pits form one plane after etching for a certain thickness. The pits thus formed have various sizes and have various curvature radii. Namely, the inner peripheral edge surface 2 is formed by an etched surface with a large number of pits having substantially different curvature radii adjacent to one another.

FIG. 2 is a scanning electron micrograph of the etched inner peripheral edge surface 2, and FIG. 3 is an enlarged sectional view schematically illustrating a cross section of part of the scanning electron micrograph. As evident from FIG. 3, the inner peripheral edge surface is an etched surface with a large number of pits 5 having different curvature radii r adjacent to one another. As the pits 5 are formed by etching fine concaves and convexes on the finish polished surface, the shape and the curvature radius r of each pit 5 vary depending upon the etching amount. Specifically, finer concaves and convexes on the finish polished surface disappear and their shapes are gradually adjusted to form pits 5 along with progress of etching. After etching is carried out in a certain amount or more, the curvature radii r of the pits 5 are stabilized and further, adjacent pits are connected with one another to form the etched surface as shown in FIGS. 2 and 3.

The etching amount is important to obtain the pits 5 having desired curvature radii r. However, the curvature radii r of the pits 5 may vary also depending upon the surface roughness of the surface subjected to finish polishing carried out prior to the etching treatment. In a case where the degree of the finish polishing is insufficient and the polished surface has a great surface roughness (Ra), not only no inner diameter with a specified dimensional accuracy will be obtained, but also a smooth inner peripheral edge surface will hardly be obtained even after the etching treatment, and no desired mechanical strength may be obtained. Accordingly, the surface roughness (Ra) of the finish polished inner peripheral edge surface is preferably at most 1.0 μm, as described hereinafter. When an inner peripheral edge surface subjected to finish polishing so that the surface roughness (Ra) is at most 1.0 μm is etched in a predetermined amount, the proportion of pits having small curvature radii can be decreased, specifically, the proportion of pits having curvature radii of at most 0.5 μm can be made to be at most about 5%.

In the present invention, in order that the etched inner peripheral edge surface 3 has desired mechanical strength and dust generation proofness, it is preferred that the amount of pits having small curvature radii r is as small as possible. Specifically, the proportion of pits having curvature radii r of at most 0.5 μm is at most 5%, preferably at most 3%. The reason why pits of at most 0.5 μm are noticed is that fine pits of at most 0.5 μm are particularly likely to generate dust. Namely, since interfaces of adjacent fine pits sharply protrude, they are likely to fracture to generate dust as fine glass particulate, and further, foreign substances attached to fine pits are hardly removed even after washing, and they are likely to generate dust. Accordingly, in the present invention, the proportion of pits of at most 0.5 μm which are likely to generate dust is at most 5%, whereby prevention of dust generation is achieved. If the proportion of pits of at most 0.5 μm is larger than 5%, dust is likely to be generated by the above reasons, which leads to a decrease in quality and a decrease in production yield of magnetic disks.

Further, the glass substrate of the present invention is preferably such that the proportion of pits having curvature radii r of at most 0.5 μm is at most 5% to all the pits on the etched surface and the proportion of pits having curvature radii of at most 1.0 μm is at most 20%, more preferably at most 18%. Even when the proportion of pits having curvature radii r of at most 0.5 μm is at most 5%, if the proportion of pits having curvature radii of at most 1.0 μm is larger than 20%, the effect of preventing dust generation may decrease from the above reasons. Further, when the proportion of pits having curvature radii r of at most 3.0 μm is at most 85% in addition, the effect of preventing dust generation will further improve. In the present invention, a glass substrate having such an etched inner peripheral edge surface also has desired mechanical strength.

In the present invention, the inner peripheral edge surface from which dust is particularly likely to be generated, consists of the above etched surface, and an etching treatment may be applied also to the outer peripheral edge surface similarly so that the outer peripheral edge surface consists of the same or substantially the same etched surface as the inner peripheral edge surface. When the outer peripheral edge surface is also etched, it is possible to reduce the amount of dust generation from the outer peripheral edge surface thereby to reduce the total amount of dust generation from the glass substrate. Further, an etching treatment may be applied to the outer peripheral edge surface simultaneously with the inner peripheral edge surface, and in such a case, usually the inner and outer peripheral edge surfaces consist of substantially the same etched surfaces.

In the present invention, the curvature radii r of the pits are measured in accordance with the following procedure (hereinafter referred to as method for measuring curvature radii).

(1) The etched surface is photographed by means of VIOLET LASER (VK-9500) apparatus (manufactured by KEYENCE CORPORATION).

(2) After plane correction by means of recursion, a smoothing treatment is applied by means of a median filter to carry out noise rejection.

(3) An average size (diameter) of pits is estimated, and a pit is specified employing the size of the diameter as a search area size, and the deepest point in the pit is taken as the bottom (bottom of dent).

(4) After the bottom is determined by the above method, the curvature is determined by least squares method based on local height information around the bottom, and the curvature radius r is determined from the obtained curvature.

The proportion of pits having predetermined curvature radii r is determined by measuring the number of pits and the curvature radii r of the pits in an area with predetermined dimensions (unit area: 1×10⁻⁴ cm²) optionally selected from the etched surface, by the above method.

The glass substrate for a magnetic disk of the present invention is typically produced by subjecting an inner peripheral edge surface of a doughnut-type glass substrate having a circular hole at its center to finish polishing so that the surface roughness (Ra) is at most 1.0 μm, and then applying an etching treatment to the finish polished surface in an etching amount of at least 2.5 μm. For example, in a case where an etching treatment is applied to an inner peripheral edge surface of a glass substrate, as mentioned above, firstly the inner peripheral edge surface is subjected to finish polishing so that the surface roughness (Ra) is at most 1.0 μm, more preferably at most 0.7 μm. The finish polishing may suitably be carried out by applying mechanical finish polishing by means of abrasive grains of from #200 to 1,000 mesh for example. If the surface roughness (Ra) exceeds 1.0 μm, it tends to be difficult to obtain an etched surface with desired smoothness even if an etching treatment is carried out in an etching amount of at least 2.5 μm, and mechanical strength of the inner peripheral edge surface may be impaired. Further, when lapping is applied to the surface to be etched so that the surface roughness (Ra) is at most 1.0 μm, since no deep scars by polishing will remain, the etching treatment is likely to be controlled, and a favorable etched surface with small dispersion of pits will be obtained.

Further, in the present invention, the etching treatment is applied to the polished surface to which mechanical finish polishing is applied, in an etching amount of at least 2.5 μm, preferably at least 5.0 μm. If the etching amount is less than 2.5 μm, it tends to be difficult to obtain an etched surface on which pits are continuously adjacent to one another, to bring the proportion of pits having curvature radii r of at most 0.5 μm to be at most 5%, and to sufficiently remove scars formed by the finish polishing. Considering these points and the dispersion in the finish polishing, the etching amount is preferably at least 5.0 μm.

For the etching treatment, a common etching method for glass, such as a wet etching method by means of an etching liquid or a dry etching method by means of an etching gas, may, for example, be used. Among them, a wet etching method employing an etching liquid such as a hydrofluoric acid solution, a hydrofluoric sulfuric acid solution, a hydrofluoric nitric acid solution or silicofluoric acid, can be suitably employed. Particularly preferred is a method employing a hydrofluoric sulfuric acid solution or a hydrofluoric nitric acid solution.

In a case where the outer peripheral edge surface of the glass substrate is also to consist of an etched surface similar to the inner peripheral edge surface, such a surface can be realized substantially in the same manner as in the case of the inner peripheral edge surface.

The inner peripheral edge surface which is an etched surface of the glass substrate of the present invention may be covered with a protective film obtained by curing e.g. a coating composition containing a polysilazane.

Further, in the process for producing a glass substrate of the present invention, after an etching treatment is applied to the inner peripheral edge surface of the glass substrate, e.g. a coating composition containing a polysilazane may be applied to the inner peripheral edge surface, followed by curing.

Now, the present invention will be described in further detail with reference to Examples. However, it should be understood that the present invention is by no means restricted to such specific Examples.

Doughnut-type glass substrates having an outer diameter of 65 mm, an inner diameter of 20 mm and a thickness of 0.9 mm were prepared from a glass plate having a composition comprising, as calculated as oxides, 66 mass % of SiO₂, 5 mass % of Al₂O₃, 0.04 mass % of Fe₂O₃, 5 mass % of Na₂O, 5 mass % of K₂O, 3 mass % of MgO, 6 mass % of CaO, 4 mass % of BaO, 5 mass % of SrO and 2 mass % of ZrO₂. The brittleness index of this glass plate was 7,800 m^{-1/2}.

The front and back surfaces and the inner and outer peripheral edge surfaces of the doughnut-type glass substrates were subjected to finish polishing with diamond abrasive grains smaller than #500 mesh, and then the front and back main surfaces of the doughnut-type glass substrates were subjected to lapping with alumina abrasive grains having an average particle size of 9 μm to obtain doughnut-type glass substrates having a surface roughness (Ra) of 0.5 μm.

### EXAMPLE 1

The above doughnut-type glass substrates were immersed in a hydrofluoric sulfuric acid solution containing 5% each of hydrofluoric acid and sulfuric acid to apply an etching treatment to the front and back surfaces and the inner and outer peripheral edge surfaces of the doughnut-type glass substrates in etching amounts of 0 μm (no etching treatment applied), 2.5 μm, 5.0 μm, 12.5 μm and 25.0 μm by changing the immersion time, whereby five types of doughnut-type glass substrates were prepared.

With respect to the five types of doughnut-type glass substrates to which an etching treatment was applied, the etched inner peripheral edge surface of each substrate was photographed by means of a VIOLET LASER (VK-9500) apparatus (manufactured by KEYENCE CORPORATION), the curvature radii r of pits constituting the etched surface were measured by means of the above method for measuring curvature radii, and the maximum of r, the minimum of r, the average of r, and the number of pits and their proportion (%) per every range of r, were obtained. The results are shown in Table 1. In Table 1, the number of pits per every range of r is a number per 1×10⁻⁴ cm² of the etched surface.

TABLE 1

Sample

| | No. 1 | | No. 2 | | No. 3 | | No. 4 | | No. 5 | |
|---|---|---|---|---|---|---|---|---|---|---|
| Etching amount | 0 | | 2.5 | | 5.0 | | 12.5 | | 25.0 | |
| (μm) | | | | | | | | | | |
| Maximum of r | 37.34 | | 21.55 | | 22.36 | | 29.20 | | 59.12 | |
| (μm) | | | | | | | | | | |
| Minimum or r | 0.16 | | 0.25 | | 0.64 | | 3.74 | | 8.38 | |
| (μm) | | | | | | | | | | |
| Average of r (μm) | 1.58 | | 2.30 | | 3.14 | | 11.40 | | 24.15 | |
| | Number | Proportion | Number | Proportion | Number | Proportion | Number | Proportion | Number | Proportion |
| Range of r (μm) | of pits | (%) | of pits | (%) | of pits | (%) | of pits | (%) | of pits | (%) |
| 0 to less than 5 | 1692 | 96.85 | 568 | 94.20 | 74 | 93.67 | 1 | 2.04 | 0 | 0 |
| 5 to less than 10 | 39 | 2.23 | 25 | 4.15 | 4 | 5.06 | 13 | 26.53 | 0 | 0 |
| 10 to less than 15 | 8 | 0.46 | 6 | 1.00 | 0 | 0 | 31 | 63.27 | 4 | 5.00 |
| 15 to less than 20 | 3 | 0.17 | 3 | 0.50 | 0 | 0 | 2 | 4.08 | 17 | 21.25 |
| 20 to less than 25 | 1 | 0.06 | 1 | 0.17 | 1 | 1.27 | 1 | 2.04 | 8 | 10.00 |
| 25 to less than 30 | 1 | 0.06 | 0 | 0 | 0 | 0 | 1 | 2.04 | 10 | 12.50 |
| 30 to less than 35 | 1 | 0.06 | 0 | 0 | 0 | 0 | 0 | 0 | 16 | 20.00 |
| 35 to less than 40 | 2 | 0.11 | 0 | 0 | 0 | 0 | 0 | 0 | 16 | 20.00 |
| 40 to less than 45 | 0 | 0 | 0 | 0 | 0 | 0 | 0 | 0 | 7 | 8.75 |
| 45 or larger | 0 | 0 | 0 | 0 | 0 | 0 | 0 | 0 | 2 | 2.50 |

It is found from Table 1 that the number of pits having small curvature radii r decreases along with an increase in the etching amount, and when the etching amount is at least 2.5 μm, the number of pits having small curvature radii r which are likely to generate dust, such as pits of at most 5 μm, remarkably decreases.

### EXAMPLE 2

With respect to the doughnut-type glass substrates of Example 1, the dust generation amount was measured in accordance with the following method. With respect to the pits having curvature radii r of 0 to less than 5 μm in Table 1, they were further classified, and each proportion is shown. The results are shown in Table 2. In Table 2, r is represented by μm, and the proportion is represented by %.

Method of Measuring Dust Generation Amount

Employing an ultrasonic cleaner 7 (manufactured by Branson, output: 120 W, frequency: 47 kHz) and a liquid particle counter 10 as shown in FIG. 4, ultrasonic waves are applied to a doughnut-type glass substrate 6 in a liquid, and the amount of particles generated by application of ultrasonic waves (dust generation amount) is measured by means of the liquid particle counter 10, to determine the dust generation amount of the doughnut-type glass substrate 6, in the following procedure.

(1) Measurement of Amount of Particles in Ultrapure Water

200 ml of ultrapure water 9 is put in a beaker 8, and the particle amount (A) per 1 ml of the ultrapure water is measured by means of a liquid particle counter 10.

(2) Then, a doughnut-type glass substrate 6 is put in the beaker 8, the beaker 8 is put in an ultrasonic cleaner 7 in which water is put, and ultrasonic waves are applied for 1 minute, the beaker 8 is taken out from the ultrasonic cleaner 7, and the particle amount (B) per 1 ml of water in the beaker is measured by means of the liquid particle counter 10.

(3) The dust generation amount (C) of the doughnut-type glass substrate 6 is calculated from {the dust generation amount (particles/sheet) of the doughnut-type glass substrate 6}={(B)−(A)}×200.

TABLE 2

| Etching | Dust generation | | | | | | |
|---|---|---|---|---|---|---|---|
| amount | amount | r ≦ 0.5 | r ≦ 1.0 | r < 1.5 | r < 2.0 | r < 2.5 | r < 3.0 |
| (μm) | (particles/sheet) | proportion | proportion | proportion | proportion | proportion | proportion |
| 0 | 13161 | 9.7 | 44.9 | 69.4 | 80.9 | 88.0 | 91.8 |
| 2.5 | 1899 | 2.2 | 17.7 | 37.5 | 56.2 | 70.6 | 80.9 |
| 5.0 | 394 | 0 | 3.8 | 10.1 | 25.3 | 49.4 | 59.5 |
| 12.5 | 147 | 0 | 0 | 0 | 0 | 0 | 0 |
| 25.0 | 35 | 0 | 0 | 0 | 0 | 0 | 0 |

It is found from Table 2 that the dust generation amount decreases along with an increase in the etching amount, in the doughnut-type glass substrate having no etching treatment applied thereto, the proportion of pits having r of at most 0.5 μm is 9.7%, and the dust generation amount is 13,161 particles, whereas in the doughnut-type glass substrate having an etching treatment applied thereto with an etching amount of 2.5 μm, the proportion of pits having r of at most 0.5 μm is 2.2%, the proportion of pits having r of at most 1 μm is 17.7%, and the dust generation amount decreases to about 1,900 particles. The dust generation amount shown in Table 2 is the dust generation amount of the entire doughnut-type glass substrate 6. The effect of preventing dust generation can be calculated from the dust generation amount of an inner peripheral edge surface of a doughnut-type glass substrate to which an etching treatment is applied similarly and the area ratio of the etched surface, based on the dust generation amount shown in Table 2.

### EXAMPLE 3

Doughnut-type glass substrates having an outer diameter of 65 mm, an inner diameter of 20 mm and a thickness of 0.635 mm were prepared from the above glass plate.

The glass substrates were immersed in a hydrofluoric sulfuric acid solution containing 5% each of hydrofluoric acid and sulfuric acid, to apply an etching treatment to the front and back surfaces and the inner and outer peripheral edge surfaces of the glass substrates, in etching amounts of 0 μm (no etching treatment applied), 4 μm, 12 μm, 17.5 μm, 25 μm and 35 μm by changing the immersion time, whereby six types of glass substrates were prepared.

These six types of glass substrates were subjected to a pressed break strength test to measure mechanical strength (unit: kgf). The results are shown in Table 3 in connection with the etching amount (unit: μm).

TABLE 3

| | Etching amount | | | | | |
|---|---|---|---|---|---|---|
| | 0 | 4 | 12 | 17.5 | 25 | 35 |
| Mechanical | 6.36 | 17.77 | 20.03 | 26.78 | 34.75 | 34.34 |
| strength | | | | | | |

According to the present invention, a high quality glass substrate for a magnetic disk, which has desired mechanical strength and from which the dust generation amount is small, can be provided.

The entire disclosure of Japanese Patent Application No. 2004-363495 filed on Dec. 15, 2004 including specification, claims, drawings and summary is incorporated herein by reference in its entirety.

What is claimed is:

1. A doughnut-type glass substrate for a magnetic disk having a circular hole at its center, characterized in that its inner peripheral edge surface is an etched surface with a large number of pits having different curvature radii adjacent to one another, and the proportion of pits having curvature radii r of at most 0.5 μm is at most 5% to all the pits on the etched surface.

2. The glass substrate for a magnetic disk according to claim 1, wherein the proportion of pits having curvature radii r of at most 1.0 μm is at most 20% to all the pits on the etched surface.

3. The glass substrate for a magnetic disk according to claim 1, wherein the proportion of pits having curvature radii r of at most 3.0 μm is at most 85% to all the pits on the etched surface.

4. The glass substrate for a magnetic disk according to claim 1, wherein the glass for the doughnut-type glass substrate has a total content of alkali metal oxides of from 6 to 12 mass %.

5. The glass substrate for a magnetic disk according to claim 1, wherein the glass for the doughnut-type glass substrate has a brittleness index of at least 5,500 m^{-1/2}.

6. The glass substrate for a magnetic disk according to claim 1, wherein the inner peripheral edge surface is covered with a protective film.

7. A process for producing a glass substrate for a magnetic disk as defined in claim 1, which comprises subjecting the inner peripheral edge surface of the doughnut-type glass substrate to finish polishing so that the surface roughness Ra is at most 1.0 μm, and then applying an etching treatment to the finish polished surface in an etching amount of at least 2.5 μm.

8. The process for producing a glass substrate for a magnetic disk according to claim 7, wherein the etching treatment is carried out by means of a hydrofluoric acid solution or a hydrofluoric sulfuric acid solution.

9. A process for producing a glass substrate for a magnetic disk, which comprises subjecting an inner peripheral edge surface of a doughnut-type glass substrate having a circular hole at its center, made of a glass having a total content of alkali metal oxides of from 6 to 12 mass %, to finish polishing so that the surface roughness Ra is at most 1.0 μm, and then applying an etching treatment to the finish polished surface in an etching amount of from 2.5 to 25 μm.

10. The process for producing a glass substrate for a magnetic disk according to claim 9, wherein the etching treatment is carried out by means of a hydrofluoric acid solution or a hydrofluoric sulfuric acid solution.
